(19) United States
(12) Patent Application Publication
(10) Pub. No.: US 2008/0191276 A1
(43) Pub. Date: Aug. 14, 2008

(54) Semiconductor devices and fabrication methods thereof

(75) Inventors: Chi-Chih Chen, Hsinchu (TW); Yi-Chun Lin, Hsinchu (TW); Kuo-Ming Wu, Hsinchu (TW); Ruey-Hsin Liu, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD.

(21) Appl. No.: 11/703,678

(22) Filed: Feb. 8, 2007

(51) Int. Cl. H01L 29/76; H01L 21/336

(52) U.S. Cl. 257/343; 438/300; 257/E29.255; 257/E21.409

(57) ABSTRACT

Semiconductor devices and fabrication methods thereof. The semiconductor device includes a semiconductor substrate with a body region of a first doping type. A gate structure is patterned on the semiconductor substrate. A single spacer is formed on a first sidewall of the gate structure. A body region of a first doping type is formed in the semiconductor substrate adjacent to a second sidewall of the gate structure. A source region of a second doping type is formed on the body region and having an edge aligned with the second sidewall of the gate structure. A drain region of the second doping type is formed on the semiconductor substrate and having an edge aligned with an exterior surface of the single sidewall.

### BACKGROUND OF THE INVENTION

1. Field of the Invention

The invention relates to semiconductor devices, and more particularly to lateral double diffused metal oxide semiconductor field effect transistor (LDMOS-FET) devices and fabrication methods thereof.

2. Description of the Related Art

High voltage technologies are suitable for high-voltage and high-power integrated circuits. One type of high-voltage semiconductor device utilizes a double diffused drain (DDD) CMOS structure. Another uses a lateral diffused MOS (LDMOS) structure, for high voltages of or less than 18V application. High-voltage technologies provide cost effective and flexible manufacturing processes for display driver ICs, power supplies, power management, telecommunications, automotive electronics and industrial controls.

FIG. 1 is a cross section of a conventional LDMOS-FET device. As shown, a conventional LDMOS-FET device includes a P-type semiconductor substrate 110 with an N-type doped well 115 in the upper region thereof. A P-type doped region 120 or P_{body} region is formed in the N-type doped well 115. A gate stacked structure comprises a gate electrode 160, a gate dielectric layer 150 and spacers 170 on the lateral walls of the gate electrode 160. A heavily N-type doped source region 140 and a heavily N-type doped drain region 130 are separately formed in the P-type semiconductor substrate 110. The heavily N-type doped drain region 130 is formed in the N-type doped well 1115. The heavily N-type doped source region 140 is formed in the P-type doped region 120 or P_{body} region. The source region 140 and the drain region 130 are disposed on both sides of the gate stacked structure with a channel region therebetween when a predetermined threshold voltage is applied. In operation, stable and low resistance between drain region 130 and source region 140 at on-state R_{dson} is critical for high-voltage and high-power LDMOS-FET devices.

Methods for fabricating high-voltage and high-power LDMOS-FET devices are also disclosed in U.S. Pat. No. 6,762,458, the entirety of which is hereby incorporated by reference. A high-voltage transistor includes a semiconductor substrate with first, second, and third regions. The first and second drift regions are respectively formed in the second and third regions at a first depth. Insulating films are formed at a second depth less than the first depth, having a predetermined width respectively based on the boundary between the first and second regions and the boundary between the first and third regions. A gate insulating film is formed on a channel ion injection region, partially overlapping the insulating films at both sides around the channel ion injection region. Drain and source regions are formed within the first and second drift regions, respectively, and a gate electrode is formed to surround the gate insulating film and partially overlap the insulating films.

FIGS. 2A-2E are cross sections illustrating fabrication of a conventional LDMOS-FET device. Referring to FIG. 2A, a semiconductor substrate 200 is provided. The semiconductor substrate 200 is preferably a P-type semiconductor substrate with an N-type doped well in the upper region thereof. A dielectric layer 250a is formed on the semiconductor substrate 200. A polysilicon layer 260a is formed on the dielectric layer 250a. A patterned mask 280 is disposed on the polysilicon layer 260a to define a gate stack with a gate 260 on the gate dielectric layer 250.

Referring to FIG. 2B, an insulating layer 270a is conformably formed on the gate stack and the semiconductor substrate 200. The insulating layer 270a includes silicon oxide, silicon nitride or complex layers of silicon oxide-nitride-oxide (ONO). The insulating layer 270a is anisotropically etched to spacers on the sidewalls of the gate stacked structure 265, as shown in FIG. 2C.

Referring to FIG. 2D, a patterned photoresist 282 is formed on the semiconductor substrate 200 covering the gate structure and the semiconductor substrate 200 at one side of the gate stacked structure 265. The semiconductor substrate 200 at the other side of the gate stacked structure 265 is exposed to ion implantation 30. The ion implantation 30 processes including a normal component 30A and an inclined component 30B creates a doped region 220 in the semiconductor substrate 200. The normal component 30A of ion implantation comprises high energy and low azimuth angle to create a deeply doped region. The inclined component 30B of ion implantation comprises low energy and high azimuth angle to control threshold voltage V_{T} of the LDMOS-FET devices.

Referring to FIG. 2E, a mask 285, such as a patterned photoresist is formed on the semiconductor substrate 200 exposing regions corresponding to source and drain regions. An ion implantation 40 is performed on the exposed regions to create source region 240 and drain region 230.

Conventional fabrication methods for LDMOS-FET devices use a P_{body} mask to define the P_{body} region of the LDMOS-FET devices. Limitation of the process window of the patterned photoresist 282, however, may cause some problems of the LDMOS-FET devices. More specifically, peak concentration of P_{body} implantation occurs in the polysilicon gate when the P_{body} mask (e.g., photoresist 282) is misaligned with an edge of the polysilicon gate. For example, misalignment of the patterned photoresist 282 may cause damage to the polysilicon gate and the semiconductor due to the normal component 30A of ion implantation resulting in unstable threshold voltage Vₜ. The process window of the normal component 30A of ion implantation is also narrow to prevent damage to the polysilicon gate and the semiconductor. Furthermore, boron penetration into the silicon surface will affect Vₜ stability of the LDMOS-FET device.

A hard mask 275 can optionally be formed on the polysilicon gate 260 to prevent damage to the polysilicon gate 260 and the semiconductor substrate 200 in conventional fabrication process. Formation of the hard mask 275, however, is time-consuming and requires additional thermal budgets, deteriorating performance of the LDMOS-FET devices.

### BRIEF SUMMARY OF THE INVENTION

Accordingly, the invention is directed to a high-voltage or high-power lateral diffused metal oxide semiconductor field effect transistor (LDMOS-FET) device, using two-step lithography to create a gate stack with a single spacer on one of the lateral sidewalls. The source and drain regions formed by lateral diffused ion implantation achieve a more stable threshold voltage Vₜ and lower R_{dson} of the LDMOS-FET device.

The invention provides a semiconductor device, comprising a semiconductor substrate, a gate structure patterned on the semiconductor substrate, a single spacer formed on a first sidewall of the gate structure, a body region of a first doping type formed in the semiconductor substrate adjacent to a second sidewall of the gate structure, a source region of a second doping type formed on the body region and having an edge aligned with the second sidewall of the gate structure, a drain region of the second doping type formed on the semiconductor substrate and having an edge aligned with an exterior surface of the single spacer.

The invention further provides a method for fabricating a semiconductor device, comprising forming a stack structure including a dielectric layer and a conductive layer on a semiconductor substrate, patterning the conductive layer and the dielectric layer to expose a first region of the semiconductor substrate, thereby creating a first sidewall of the stack structure, forming a single spacer on the first sidewall of the stack structure, forming a first mask covering a portion of the stack structure, the single spacer, and the first region of the semiconductor substrate, removing the conductive layer and the dielectric layer not covered by the first mask to expose a second region of the semiconductor substrate, thereby creating a second sidewall of the stack structure, performing a first ion implantation process comprising a normal ion implantation and a lateral ion implantation to form a body region on the exposed second region of the semiconductor substrate, removing the first mask, performing a second ion implantation process to form a source region in the body region and a drain region on the first region of the semiconductor substrate, wherein the source region has an edge aligned with the second sidewall of the gate structure, and the drain region has an edge aligned with an exterior surface of the single spacer.

### BRIEF DESCRIPTION OF DRAWINGS

The invention can be more fully understood by reading the subsequent detailed description and examples with references made to the accompanying drawings, wherein:

FIG. 1 is a cross section of a conventional LDMOS-FET device;

FIGS. 2A-2E are cross sections illustrating fabrication steps of a conventional LDMOS-FET device;

FIGS. 3A-3E are cross sections illustrating fabrication steps of an exemplary LDMOS-FET device of the invention; and

FIG. 4 is a cross section of an exemplary embodiment of the LDMOS-FET device of the invention.

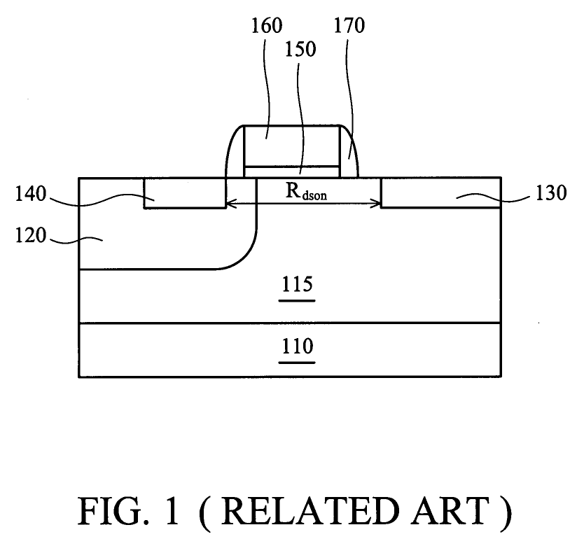

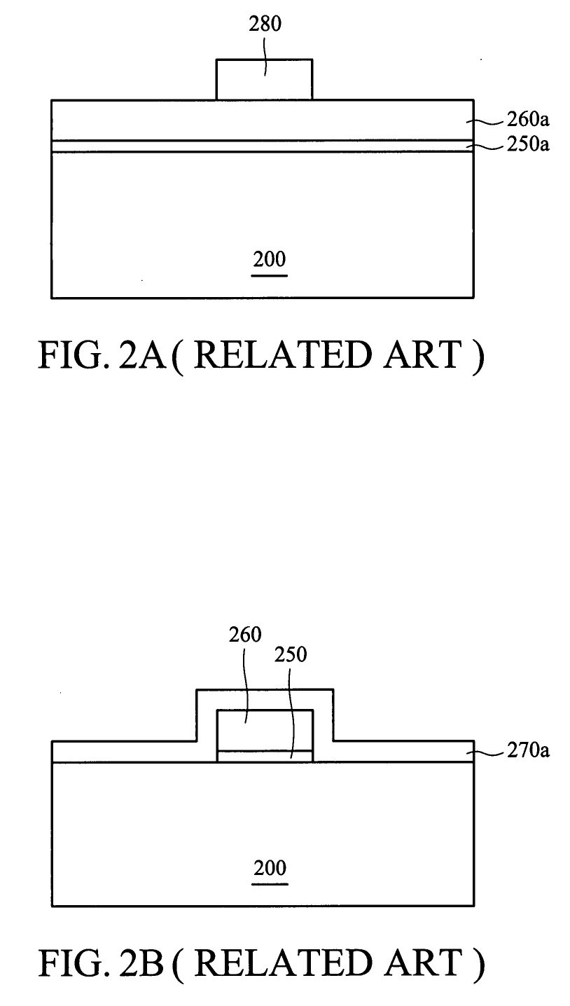

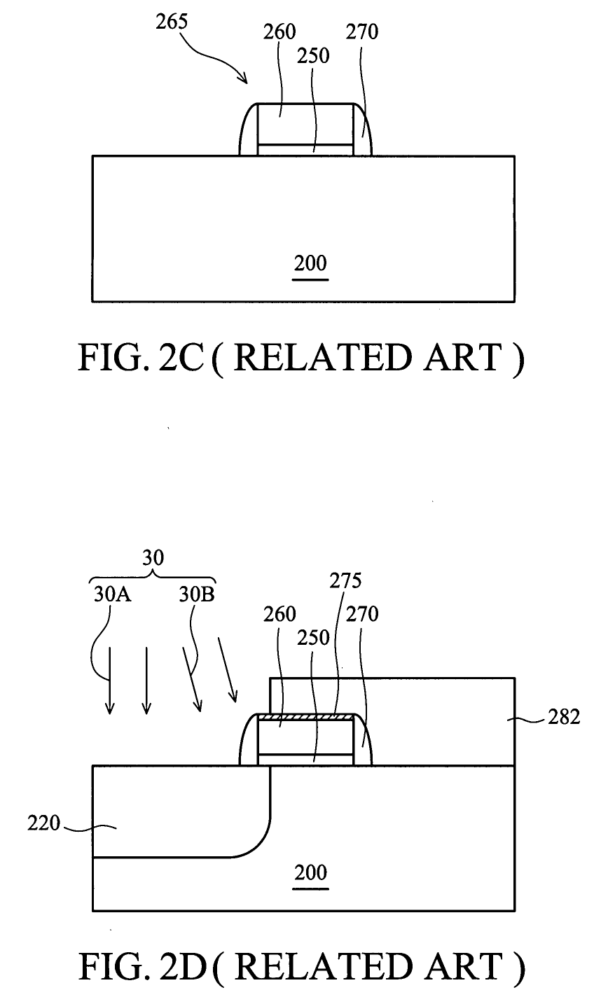

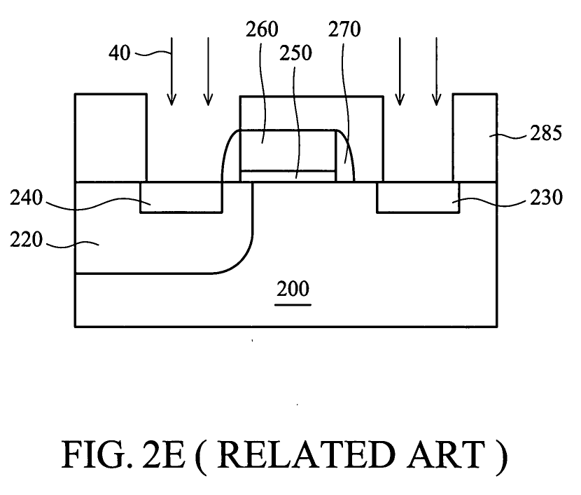

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

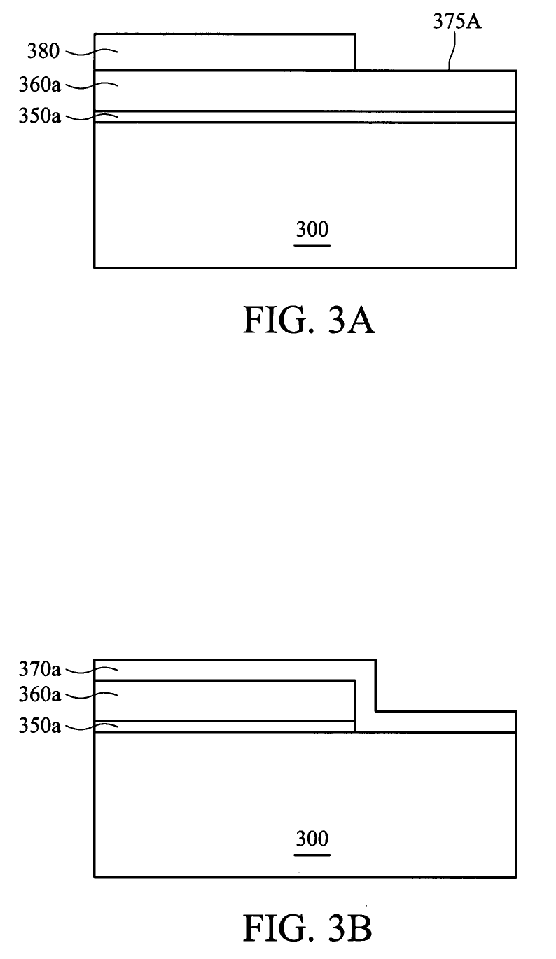

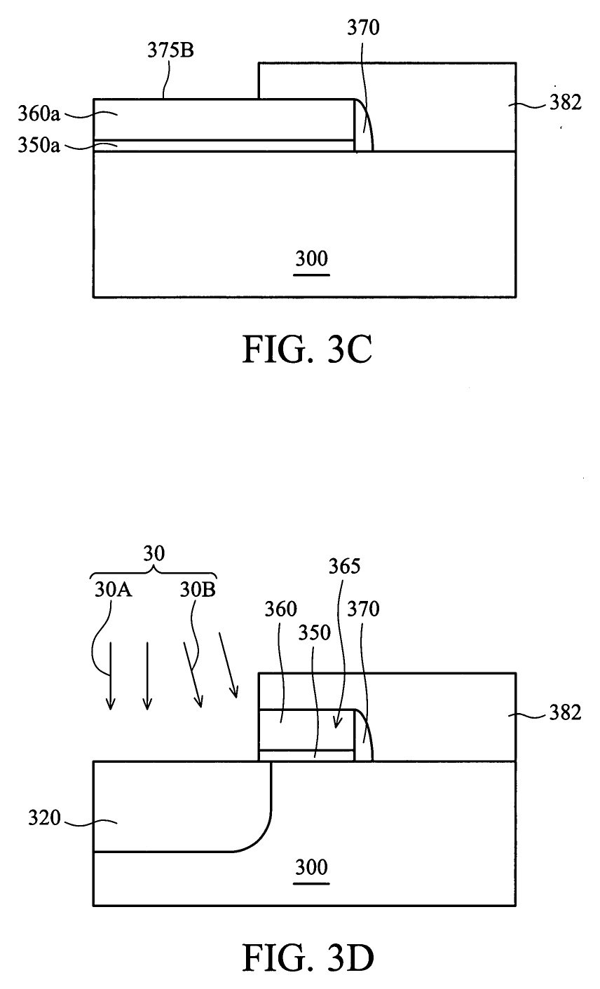

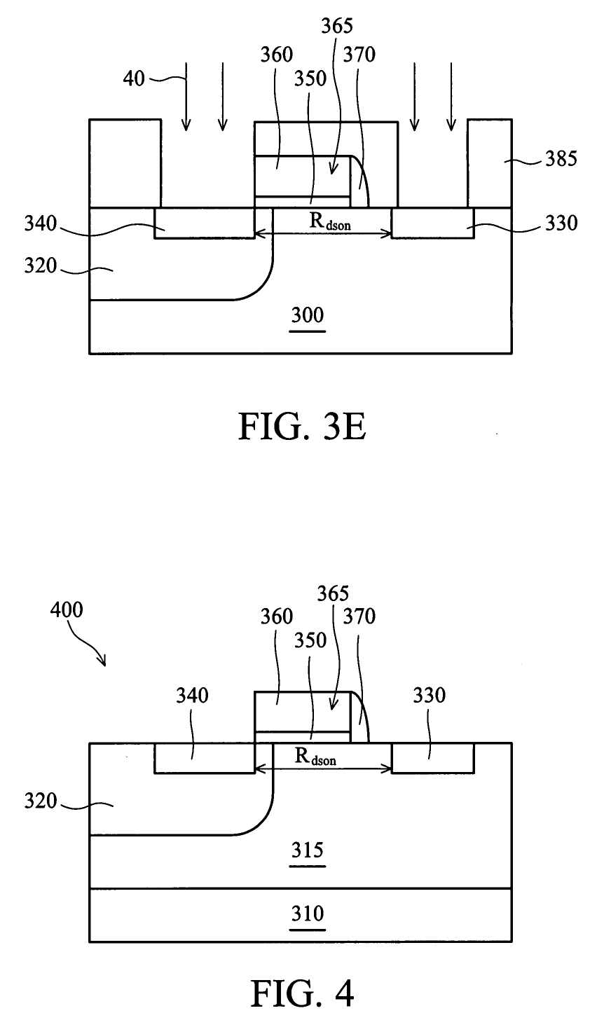

A transistor structure as disclosed is depicted in FIGS. 3A-3E. Two-step lithography creates a gate stack with a single spacer on one of the lateral sidewalls. The source and drain regions formed by lateral diffused ion implantation can achieve more stable threshold voltage Vₜ and lower R_{dson} of the LDMOS-FET device. When the gate stack receives a predetermined threshold voltage Vₜ, a resistance between the drain region and the source region is less than that of the conventional structure.

FIGS. 3A-3E are cross sections illustrating fabrication steps of an exemplary LDMOS-FET device of the invention. Referring to FIG. 3A, a semiconductor substrate 300 is provided. The semiconductor substrate 300 may comprise a bulk silicon or silicon-on-insulator (SOI) substructure. The semiconductor substrate 300 is preferably a P-type semiconductor substrate with an N-type doped well in the upper region thereof. A dielectric layer 350a is formed on the semiconductor substrate 300. A conductive layer 360a such as a polysilicon layer is formed on the dielectric layer 350a. A first mask 380 such as a patterned photoresist is disposed on the conductive layer 360a exposing a first region 375A of the conductive layer 360a. The conductive layer 360a and the dielectric layer 350a not covered by the first mask 380 are removed, exposing the semiconductor substrate 300 at the first region 375A.

Referring to FIG. 3B, a dielectric layer 370a, such as a silicon oxide layer, silicon nitride, silicon oxynitride (SiON), or complex layers of silicon oxide-nitride-oxide (ONO) is conformably formed on the semiconductor substrate 300. The dielectric layer 370a is anisotropically etched into a single spacer 370 on the sidewall of the conductive layer 360a and the dielectric layer 350a, as shown in FIG. 3C.

Referring to FIG. 3C, a second mask 382, such as a patterned photoresist, is formed on the conductive layer 360a and the semiconductor substrate 300, exposing a second region 375B of the conductive layer 360a. Then the conductive layer 360a and the dielectric layer 350a not covered by the second mask 382 are removed, exposing the semiconductor substrate 300 at the second region 375B, thereby creating a gate structure 365 with a single spacer 370 on the sidewall of the gate structure as depicted in FIG. 3D. The gate structure 365 includes a gate dielectric 350 and a gate electrode 360. The gate electrode 360 preferably comprises a polysilicon gate or a metal gate.

Referring to FIG. 3D, the semiconductor substrate 300 at the second region 375B is exposed to ion implantation 30. The ion implantation 30, including a normal component 30A and an inclined component 30B, creates a doped region 320 in the semiconductor substrate 300. The normal component 30A of ion implantation 30 comprises high energy and low azimuth angle to create a deeply doped region. The inclined component 30B of ion implantation 30 comprises low energy and high azimuth angle to control threshold voltage Vₜ of the LDMOS-FET devices. Since the second mask 382 is self-aligned, the gate structure 365 is protected by the second mask 382 from damage by the normal component 30A of ion implantation, thereby improving stable threshold voltage (Vₜ). The process windows of the normal component 30A of P_{body} region ion implantation energy and dosage can be enlarged during implantation. Furthermore, boron dopant does not penetrate into silicon surface, resulting in a stable Vₜ of the LDMOS-FET device.

Referring to FIG. 3E, a mask 385 for source and drain implantation, such as a patterned photoresist, is formed on the semiconductor substrate 300, exposing regions corresponding to source and drain regions. An ion implantation 40 is performed on the exposed regions to create source region 340 and drain region 330. Since the gate stack is adjacent to the source region without spacer thereon, the distance between the source region 340 and the drain region 330 is reduced, providing a more stable and lower R_{dson} LDMOS-FET device. Additional steps required to complete the LDMOS-FET device, not essential to an understanding of the invention, are not mentioned here.

FIG. 4 is a cross section of an exemplary embodiment of the LDMOS-FET device of the invention. The LDMOS-FET device 400 comprises a semiconductor substrate 310 with a body region 320 of a first type doped therein. The semiconductor substrate can be a P-type semiconductor substrate 310 with an N-type doped well 315 in the upper region thereof. A P-type doped region 320 or a P_{body} region is formed in the N-type doped well 315. A gate structure 365 comprising a gate electrode 360, a gate dielectric layer 350 and a single spacer 370 is formed on one of the lateral walls of the gate stack. The gate electrode 360 preferably comprises a polysilicon gate or a metal gate. A heavily N-type doped source region 340 and a heavily N-type doped drain region 330 are separately formed in the P-type semiconductor substrate 310. The heavily N-type doped drain region 330 is formed in the N-type doped well 315. The heavily N-type doped source region 140 is formed in the P-type doped region 320 or P_{body} region. The source region 340 and the drain region 330 are disposed on both sides of the gate structure with a channel region therebetween when a threshold voltage is applied. In operation, stable and low resistance between drain region 330 and source region 340 at on-state R_{dson} is critical for high-voltage and power LDMOS-FET devices. Since the gate stack is adjacent to the source region without spacer thereon, the distance between the source region 340 and the drain region 330 is reduced, thereby creating a more stable and lower R_{dson} LDMOS-FET device. Note that when the gate stack receives a predetermined threshold voltage, a resistance between the drain region and the source region is less than that of the conventional structure.

The invention is advantageous in that a two-step lithography process is used to create a gate stack with a lateral sidewall self-aligned to the P_{body} mask during P_{body} region ion implantation and with a single spacer on one of the lateral sidewalls. The process windows of the P_{body} region ion implantation energy and dosage are thereby enlarged. The source, drain region formed by lateral diffused ion implantation, provides more stable threshold voltage Vₜ and lower R_{dson} of the LDMOS-FET device. Moreover, the LDMOS-FET device and fabrication process can be integrated into all advanced high-voltage and high-power technologies.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a semiconductor substrate;
a gate structure patterned on the semiconductor substrate;
a single spacer formed on a first sidewall of the gate structure;
a body region of a first doping type formed in the semiconductor substrate adjacent to a second sidewall of the gate structure;
a source region of a second doping type formed on the body region and having an edge aligned with the second sidewall of the gate structure;
a drain region of the second doping type formed on the semiconductor substrate and having an edge aligned with an exterior surface of the single sidewall.

2. The semiconductor device as claimed in claim 1, wherein the semiconductor substrate comprises a P-type silicon substrate with an N-type well on the surface region of P-type silicon substrate.

3. The semiconductor device as claimed in claim 2, wherein the body region is a P-type doped region disposed in the N-type well.

4. The semiconductor device as claimed in claim 1, wherein the source region is a heavily doped N-type region in the body region.

5. The semiconductor device as claimed in claim 2, wherein the drain region is a heavily doped N-type region in the N-type well.

6. A method for fabricating a semiconductor device, comprising:
forming a stack structure including a dielectric layer and a conductive layer on a semiconductor substrate;
patterning the conductive layer and the dielectric layer to expose a first region of the semiconductor substrate, thereby creating a first sidewall of the stack structure;
forming a single spacer on the first sidewall of the stack structure;
forming a first mask covering a portion of the stack structure, the single spacer, and the first region of the semiconductor substrate;
removing the conductive layer and the dielectric layer not covered by the first mask to expose a second region of the semiconductor substrate, thereby creating a second sidewall of the stack structure;
performing a first ion implantation processes comprising a normal ion implantation and a lateral ion implantation to form a body region on the exposed second region of the semiconductor substrate;
removing the first mask;
performing a second ion implantation process to form a source region in the body region and a drain region on the first region of the semiconductor substrate,
wherein the source region has an edge aligned with the second sidewall of the gate structure, and the drain region has an edge aligned with an exterior surface of the single sidewall.

7. The method as claimed in claim 6, wherein the semiconductor substrate comprises a P-type silicon substrate with an N-type well on the surface region of P-type silicon substrate.

8. The method as claimed in claim 6, wherein the conductive layer comprises a polysilicon layer or a metal layer.

9. The method as claimed in claim 6, wherein the multiple ion implantation processes comprises ion implantation with P-type dopant.

10. The method as claimed in claim 6, wherein a second ion implantation process comprises heavy ion implantation with N-type dopant.
